(19) United States
(12) Patent Application Publication
(10) Pub. No.: US 2010/0176481 A1
(43) Pub. Date: Jul. 15, 2010

(54) Memory Device and Manufacturing Method Thereof

(75) Inventors: Ming-Tsung Wu, Shoufong Township (TW); Han-Hui Hsu, Tainan (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MACRONIX INTERNATIONAL CO., LTD., Hsinchu (TW)

(21) Appl. No.: 12/351,142

(22) Filed: Jan. 9, 2009

(51) Int. Cl. H01L 23/58; H01L 21/76; H01L 21/302; H01L 21/02; G11C 11/34; H01L 23/14

(52) U.S. Cl. 257/506; 438/404; 438/689; 365/174; 257/E23.004; 257/E23.008; 257/E21.002

(57) ABSTRACT

A memory device and a manufacturing method thereof are provided. The manufacturing method of memory device includes the following steps. Firstly, a substrate having a substrate surface is provided. Next, at least two memory units separated via a space are formed on the substrate. Then, an insulating layer covering the memory units and the substrate surface is formed. After that, a mask layer only covering the bottom of the insulating layer is formed on the insulating layer. Afterwards, the part of the insulating layer partially covered by the mask layer is etched. Then, the mask layer is removed. Next, the part of the insulating layer where the mask layer is removed is etched. Lastly, a protecting layer is formed on the memory units and in the space between the memory units.

### BACKGROUND OF THE INVENTION

1. Field of the Invention

The invention relates in general to a memory device and a manufacturing method thereof, and more particularly to a small-sized memory device and a manufacturing method thereof.

2. Description of the Related Art

As the design of electronic products is directed towards slimness, lightweight and compactness, the size of memory device is also reduced. A memory device is composed of several memory units. A protecting layer is formed on the memory units and in the space between the memory units to protect the memory units.

However, when the size of the memory device is reduced, the space between the memory units also reduces. As a result, during the formation of the protecting layer, the protecting layer cannot completely fill the space between the memory units, and holes will be formed. These undesired holes severely impede the miniaturization of the memory device.

### SUMMARY OF THE INVENTION

The invention is directed to a memory device and a manufacturing method thereof. By use of the design of forming the insulating side-wall of the memory device on the first lateral surface and the second lateral surface in two stages, the protecting layer smoothly fills up the space between the memory units without leaving any holes.

According to a first aspect of the present invention, a manufacturing method of memory device including the following steps is provided. Firstly, a substrate having a substrate surface is provided. Next, at least two memory units separated via a space are formed on the substrate. Then, an insulating layer covering the memory units and the substrate surface is formed. After that, a mask layer only covering the bottom of the insulating layer is formed on the insulating layer. Afterwards, the part of the insulating layer partially covered by the mask layer is etched. Then, the mask layer is removed. Next, the part of the insulating layer where the mask layer is removed is etched. Lastly, a protecting layer is formed on the memory units and in the space between the memory units.

According to a second aspect of the present invention, a memory device is provided. The memory device includes a substrate, at least two memory units, at least two insulating side-wall and a protecting layer. The substrate has a substrate surface. The memory units separated via a space are disposed on the substrate. The insulating side-walls respectively enclose the lateral side of each memory unit. Each insulating side-wall includes a first insulating portion and a second insulating portion. The first insulating portion having a first lateral surface. The second insulating portion has a second lateral surface. The first insulating portion is disposed on the second insulating portion. The protecting layer is formed on the memory units and in the space between the memory units. The contained angle between the substrate surface and each first lateral surface is smaller than 75 degrees. The contained angle between the substrate surface and each second lateral surface is smaller than 90 degrees.

The invention will become apparent from the following detailed description of the preferred but non-limiting embodiments. The following description is made with reference to the accompanying drawings.

### BRIEF DESCRIPTION OF THE DRAWINGS

FIG. 1 shows a memory device according to a preferred embodiment of the invention;

FIG. 2A shows single pitch memory units;

FIG. 2B shows dual pitch memory units;

FIG. 3 shows a flowchart of a manufacturing method of memory device according to a preferred embodiment of the invention;

FIGS. 4A˜4M show each step of FIG. 3;

Exhibt 1 shows an actual cross-section of a memory device formed according to the “double etching process of the insulating layer” of a preferred embodiment of the invention;

Exhibt 2 shows an actual cross-section of a memory device formed according to the “single etching process of insulating layer”;

Exhibt 3 shows an actual cross-section of a memory device formed according to the “overetching process of insulating layer”; and

Exhibt 4 shows an actual cross-section of a memory device formed according to the “complete removal method of insulating layer”.

### DETAILED DESCRIPTION OF THE INVENTION

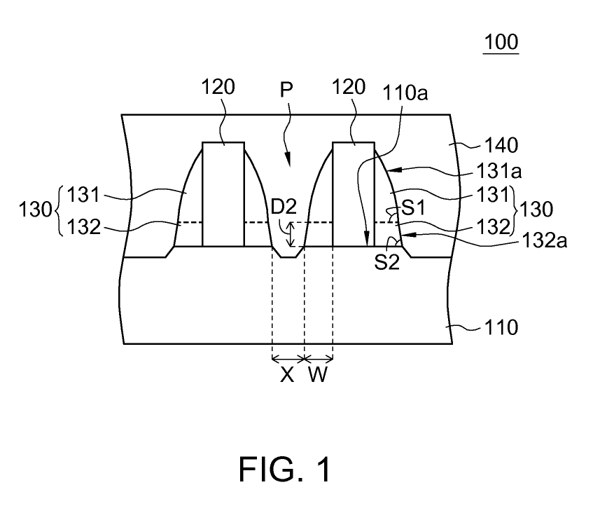

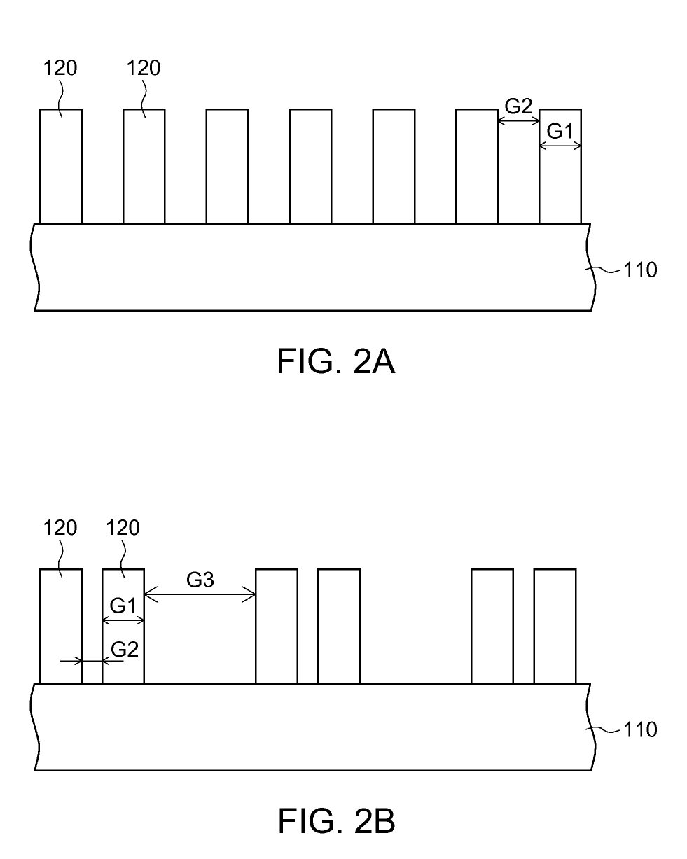

Referring to FIG. 1, a memory device 100 according to a preferred embodiment of the invention is shown. The memory device 100 includes a substrate 110, at least two memory units 120, at least two insulating side-walls 130 and a protecting layer 140. In FIG. 1, only two sets of memory units 120 and insulating side-walls 130 are illustrated. However, the memory device 100 can be composed of several sets of memory units 120 and insulating side-walls 130 that are arranged in a matrix. Reffering to FIG. 2A, FIG. 2A shows single pitch memory units. The memory units 120 may be single pitch memory units. The average pitch of single pitch memory units is equal to the sum of width G1 and gap G2. Reffering to FIG. 2B, FIG. 2B shows dual pitch memory units. The memory units 120 may be dual pitch memory units. The average pitch of dual pitch memory units is equal to the sum of width G1, one half of gap G3 and one half of gap G4. The memory units 120 are disposed on the substrate 110. The memory units 120 are separated via a space P. The insulating side-walls 130 respectively enclose the lateral side of each memory unit 120, but the neighboring insulating side-walls 130 do not contact each other. The protecting layer 140 is formed on the memory units 120 and in the space P between the memory units 120.

Each insulating side-wall 130 includes a first insulating portion 131 and a second insulating portion 132. Each first insulating portion 131 has a first lateral surface 131a. Each second insulating portion 132 has a second lateral surface 132a. Each first insulating portion 131 is located on a second insulating portion 132. The contained angle S1 between the substrate surface 110a and each first lateral surface 131a is smaller than 75 degrees. The contained angle S2 between the substrate surface 110a and each second lateral surface 132a is smaller than 90 degrees. The ratio of the height D2 of each second insulating portion 132 to the distance X between the two second insulating portions 132 is smaller than 0.6. The ratio of the thickness W of each second insulating portion 132 to the distance X between the two second insulating portions 132 ranges 0.3˜0.65. The mathematical expressions are disclosed below:

S1<75° (1)

S2<90° (2)

D2/X<0.6 (3)

0.3<W/X<0.65 (4)

By use of the design of forming the first lateral surface 131a and the second lateral surface 132a in two stages, the protecting layer 140 completely fills the space P between the memory units 120 along the shape of the insulating side-wall 130 during the formation of the protecting layer 140, and no hole will be formed.

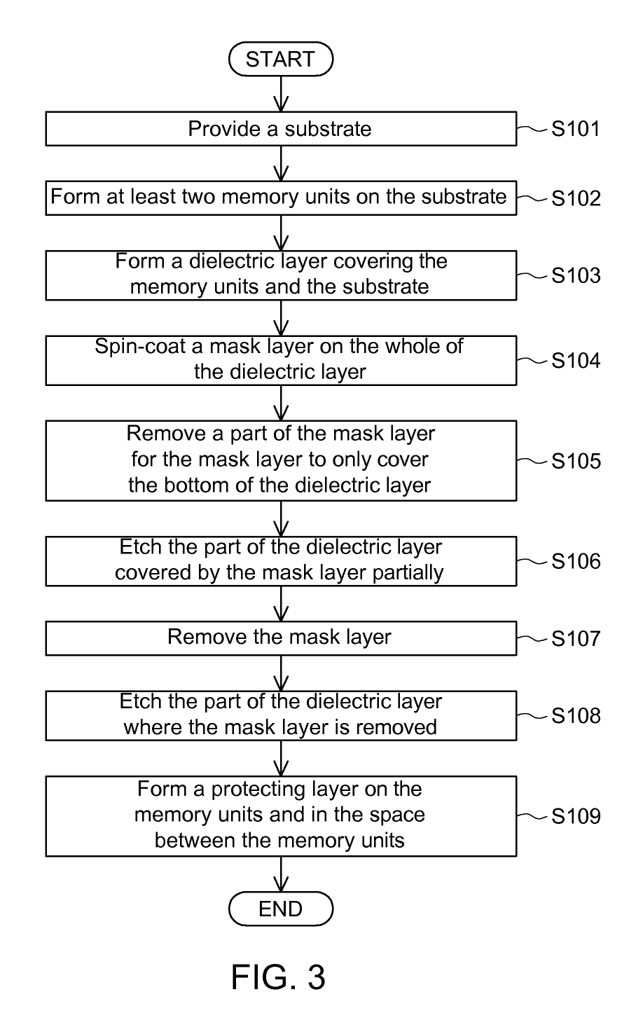

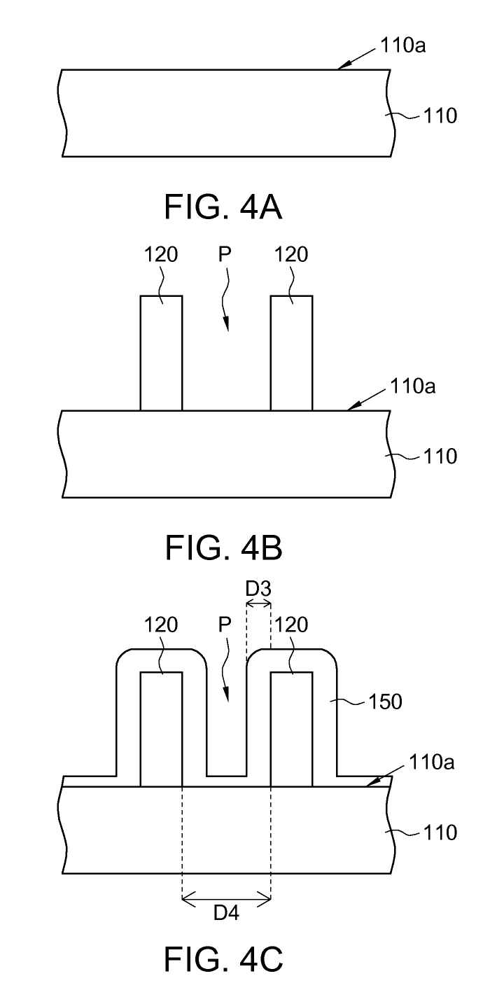

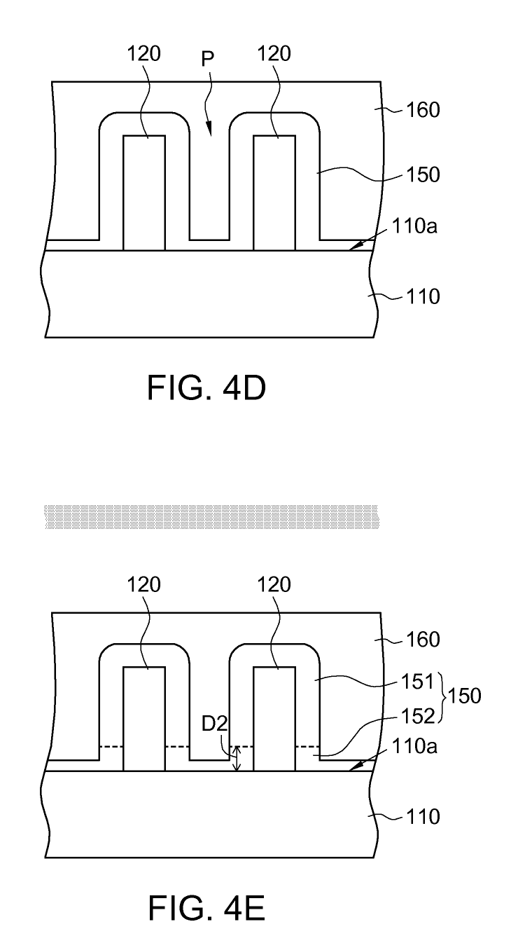

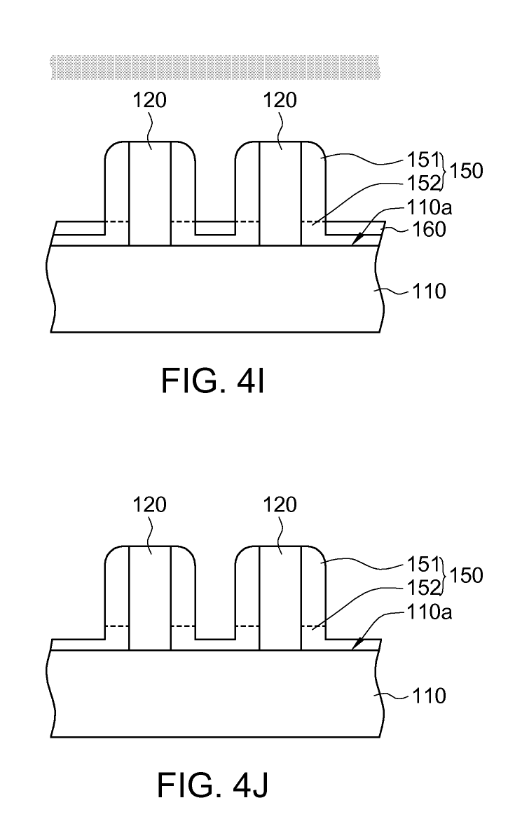

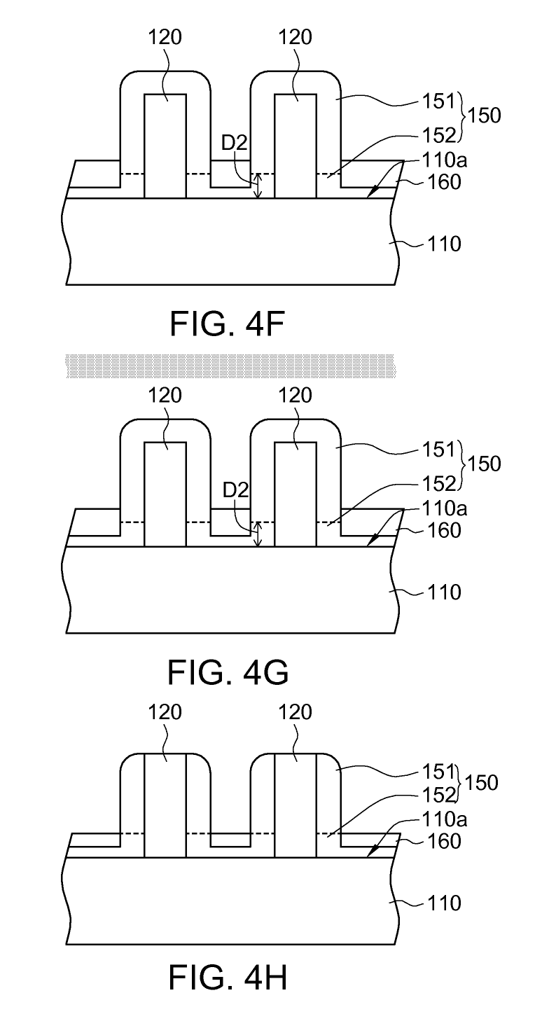

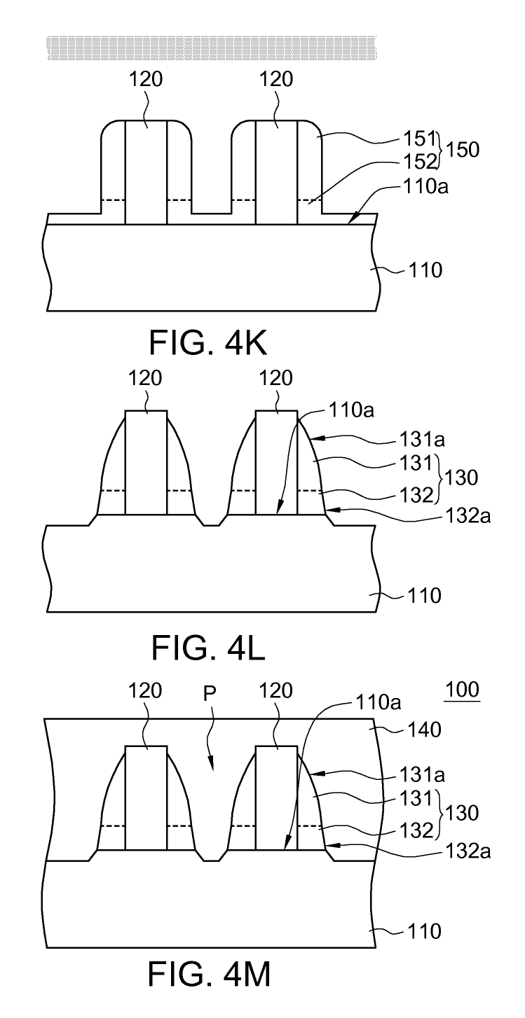

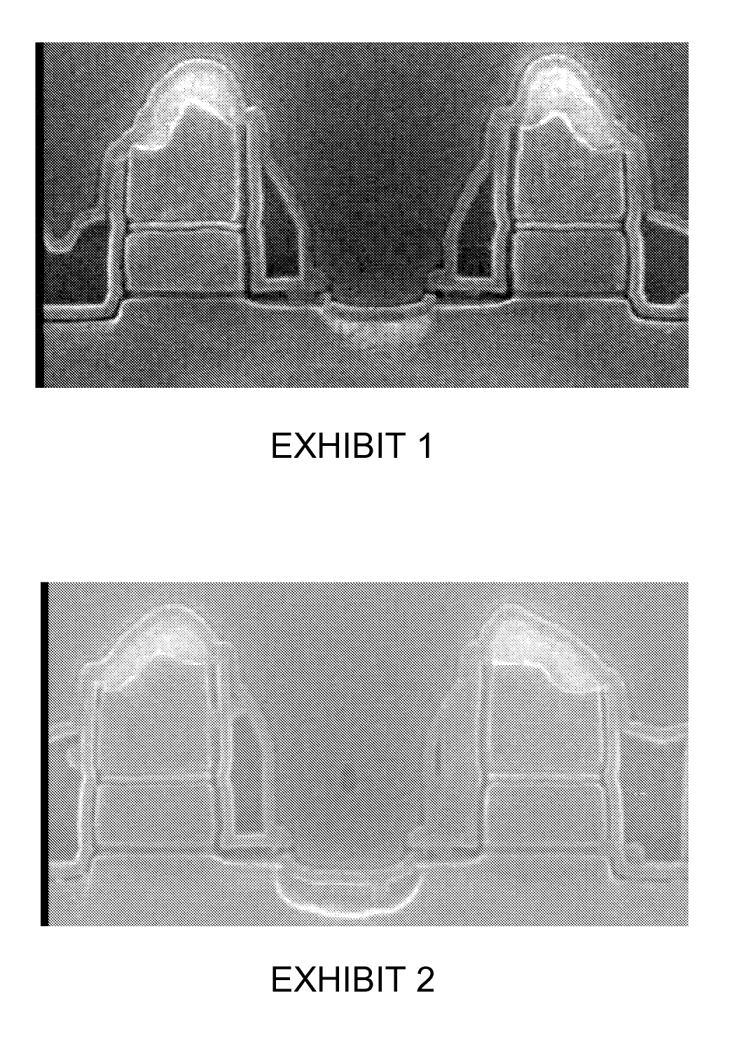

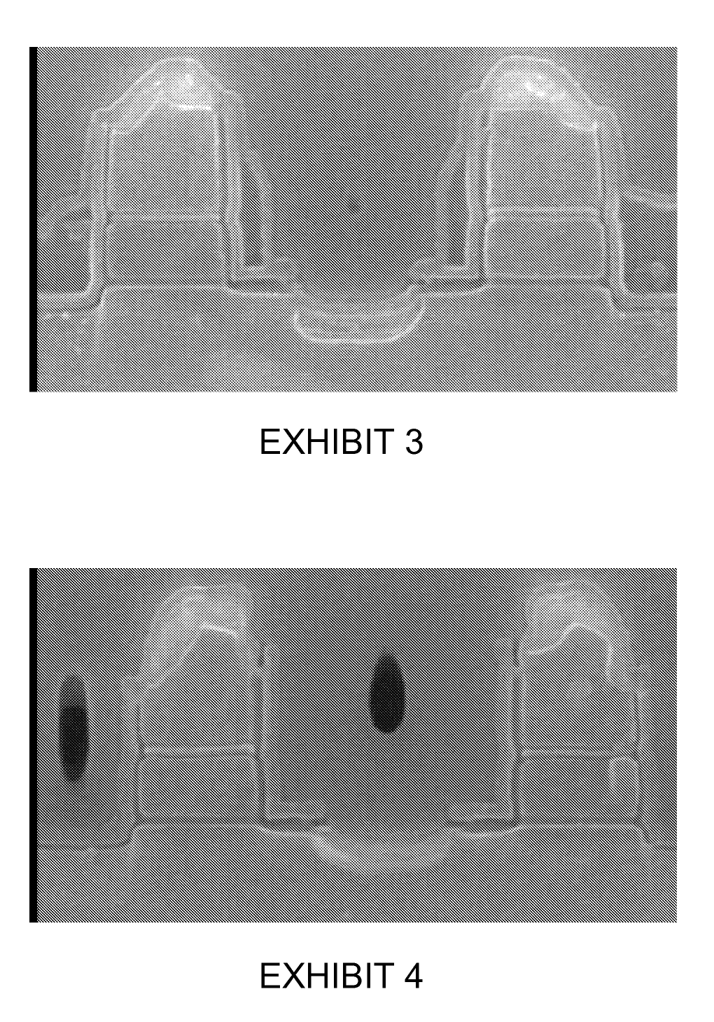

To clearly elaborate the concept of the two-stage design and how the protecting layer 140 completely fills the space P between the memory units 120 during the formation of the protecting layer 140, a flowchart of a manufacturing method of the memory device 100 of the present embodiment of the invention is disclosed below. Also, referring to FIG. 3 and FIG. 4A˜4M. FIG. 3 shows a flowchart of a manufacturing method of memory device 100 according to a preferred embodiment of the invention. FIGS. 4A˜4M show each step of FIG. 3.

Firstly, as indicated in the step S101 of FIG. 4A, a substrate 110 is provided. The substrate 110, for example, is a P-type silicon substrate or an N-type silicon substrate.

Next, as indicated in the step S102 of FIG. 4B, several memory units 120 are formed on the substrate 110. The memory units 120 are separated via a space P.

Then, as indicated in the step S103 of FIG. 4C, an insulating layer 150 covering the memory units 120 and the substrate 110 is formed. Wherein the insulating layer 150 can compreie a silicon oxide/silicon nitride/silicon oxide stack structure. In another embodiment, the insulating layer 150 can compreie silcon oxide only. In another embodiment, the insulating layer 150 can compreie silcon nitride only. In the present step, if the memory units 120 are signal pitch memory units, the insulating layer 150 does not completely fill the space P between the memory units 120 but covers the memory units 120 and the substrate 110 with a substantially uniformed thin film. In another embodiment, if the memory units 120 are dual pitch memory units, the insulating layer 150 completely fill the space P between the memory units 120. The thickness D3 of the insulating layer 150 is smaller than a half of the width D4 of the space P, hence the insulating layer 150 located between the memory units 120 will not contact each other.

The insulating layer 150 may be composed of a silicon oxide layer and a silicon nitride layer, a silicon oxide layer only, a silicon nitride layer only, or a silicon oxide/silicon oxide/silicon oxide stack structure. The formation is determined according to actual needs.

Then, as indicated in the step S104 of FIG. 4D, a mask layer 160 is spin-coated on the whole of the insulating layer 150. The mask layer 160 is made from a fluid material such as photoresist, bottom anti-reflective coating (BARC) or a combination of a photoresist layer and a bottom anti-reflective coating (BARC) layer. As the mask layer 160 is made from a fluid material, the mask layer 160 can completely fill the space P between the memory units 120 by spin-coating without leaving any hole.

After that, as indicated in the step S105 of FIG. 4E˜4F, the mask layer 160 is removed partially such that the mask layer 160 only covers the bottom 152 of the insulating layer 150. The mask layer 160 only covers the insulating layer 150 below a predetermined height (in the present embodiment of the invention, the predetermined height is slightly larger than the height D2 of the second insulating portion 132 of FIG. 1 and substantially lower than a half height of the insulating layer 150) and exposes the top 151 of the insulating layer 150 above the height D2 of the second insulating portion 132.

Then, as indicated in the step S106 of FIGS. 4G˜4H, the part of the insulating layer 150 partially covered by the mask layer 160 is etched. As the mask layer 160 covers the bottom 152 of the insulating layer 150 and exposes the top 151 of the insulating layer 150, only the top 151 of the insulating layer 150 will be etched. Wherein, in the step S106, the mask layer 160 is etchbacked, such that the thickness of the mask layer 160 is reduced. In the present step, whether the insulating layer 150 is etched to expose the memory units 120 is determined according to actual needs and is achieved by adjusting suitable parameters of the manufacturing process.

Afterwards, as indicated in the step S107 of FIGS. 4I˜4J, the mask layer 160 is removed to expose the bottom 152 of the insulating layer 150.

Then, as indicated in the step S108 of FIGS. 4K˜4L, the part of the insulating layer 150 where the mask layer 160 is removed is etched. As the mask layer 160 is removed, both the top 151 and the bottom 152 of the insulating layer 150 will be etched. The top 151 of the insulating layer 150 is etched twice and the bottom 152 of the insulating layer 150 is etched only once. Eventually, the insulating layer 150 will be etched as the insulating side-wall 130 of FIG. 4L. Each insulating side-wall 130 respectively encloses the lateral side of each memory unit 120. Each insulating side-wall 130 includes a first insulating portion 131 and a second insulating portion 132. Each first insulating portion 131 is located on a second insulating portion 132. The first lateral surface 131a of each first insulating portion 131 is flatter than the second lateral surface 132a of each second insulating portion 132.

As the step S106 and the step S108 can adopt similar conditions in the manufacturing process such as the concentration or the pressure of the etching gas, the step S106 and the S108 can be exercised at the same chamber or at different chambers respectively.

Then, as indicated in FIG. 4M, a protecting layer 140 is formed on the memory units 120 and in the space P between the memory units 120. In the present step, the first lateral surface 131a is flatter than the second lateral surface 132a, so each insulating side-wall 130 is taper and the protecting layer 140 can completely fill the space P between the memory units 120 without leaving any holes. Thus, the memory device 100 of the present embodiment of the invention is completed.

As the insulating layer 150 is etched twice in the steps S106 and S108, the insulating side-wall 130 of the memory device 100 has a first lateral surface 131a and a second lateral surface 132a and forms a two-stage design. Referring to Exhibt 1, an actual cross-section of a memory device formed according to the “double etching process of the insulating layer” of a preferred embodiment of the invention is shown. According to the empirical results as illustrated in Exhibt 1, the design of forming the first lateral surface 131a and the second lateral surface 132a in two stages effectively avoids holes during the formation of the protecting layer 140.

Referring to Exhibt 2, an actual cross-section of a memory device formed according to the “single etching process of insulating layer” is shown. According to the empirical results as illustrated in Exhibt 2, when the insulating layer is etched once, the insulating side-wall does not form a two-stage design and holes are still easily formed during the formation of the protecting layer.

Referring to Exhibt 3, an actual cross-section of a memory device formed according to the “overetching process of insulating layer” is shown. According to the empirical results as illustrated in Exhibt 3, during the single etching process of the insulating layer, despite the insulating layer is etched deeper by way of overetching process, the insulating side-wall still does not form a two-stage design and holes are easily formed during the formation of the protecting layer. Moreover, the overetching process will leave very deep indents on the substrate surface, hence severely affecting the electrical properties of the memory device.

Referring to Exhibt 4, an actual cross-section of a memory device formed according to the “complete removal method of insulating layer” is shown. According to the empirical results as illustrated in Exhibt 4, during the single etching process of the insulating layer, if the insulating layer is entirely removed without leaving any insulating side-wall, holes are formed easily during the formation of the protecting layer.

After repeated experiments, only when the memory device 100 completely satisfies the conditions as indicated in the mathematical expressions (1)˜(4) will holes be avoided during the formation of the protecting layer 140. According to simple experiments, the conditions as indicated in mathematical expressions (1)˜(4) cannot be achieved by conventional manufacturing method.

Under the conditions of meeting different product requirements and satisfying the mathematical expressions (1)˜(4), the four preferred embodiments below effectively avoid holes during the formation of the protecting layer 140.

The design of the first preferred embodiment is disclosed below. The contained angle S1 between the substrate surface 110a and each first lateral surface 131a is smaller than 70 degrees. The contained angle S2 between the substrate surface 110a and each second lateral surface 132a is smaller than 85 degrees. The ratio of the height D2 of each second insulating portion 132 to the distance X between the two second insulating portions 132 is smaller than 0.6. The ratio of the thickness W of each second insulating portion 132 to the distance between X the two second insulating portions 132 ranges 0.5˜0.65. The mathematical expressions are disclosed below:

S1<70° (5)

S2<85° (6)

D2/X<0.6 (7)

0.5<W/X<0.65 (8)

The design of the second preferred embodiment is disclosed below. The contained angle A1 between the substrate surface 110a and each first lateral surface 131a is smaller than 70 degrees. The contained angle S2 between the substrate surface 110a and each second lateral surface 132a ranges 85˜90 degrees. The ratio of the height D2 of each second insulating portion 132 to the distance X between the two second insulating portions 132 is smaller than 0.2. The ratio of the thickness W of each second insulating portion 132 to the distance X between the two second insulating portions 132 ranges 0.3˜0.5. The mathematical expressions are disclosed below:

S1<70° (9)

85°<S2<90° (10)

D2/X<0.2 (11)

0.3<W/X<0.5 (12)

The design of the third preferred embodiment is disclosed below. The contained angle S1 between the substrate surface 110a and each first lateral surface 131a ranges 70˜75 degrees. The contained angle S2 between the substrate surface 110a and each second lateral surface 132a is smaller than 85 degrees. The ratio of the height D2 of each second insulating portion 132 to the distance X between the two second insulating portions 132 is smaller than 0.4. The ratio of the thickness W of each second insulating portion 132 to the distance X between the two second insulating portions 132 ranges 0.3˜0.5. The mathematical expressions are disclosed below:

70°<S1<75° (13)

S2<85° (14)

D2/X<0.4 (15)

0.3<W/X<0.5 (16)

The design of the fourth preferred embodiment is disclosed below. The contained angle S1 between the substrate surface 110a and each first lateral surface 131a ranges 70˜75 degrees. The contained angle S2 between the substrate surface 110a and each second lateral surface 132a ranges 85˜90 degrees. The ratio of the height D2 of each second insulating portion 132 to the distance X between the two second insulating portions 132 is smaller than 0.2. The ratio of the thickness W of each second insulating portion 132 to the distance X between the two second insulating portions 132 ranges 0.4˜0.6. The mathematical expressions are disclosed below:

70°<S1<75° (17)

85°<S2<90° (18)

D2/X<0.2 (19)

0.4<W/X<0.6 (20)

The design of each of the above preferred embodiments is not merely a selection of size. When one condition of the four mathematical expressions (1)˜(4) is adjusted in order to meet product requirements, the other three conditions must be adjusted accordingly such that desired effect can be achieved. Thus, each of the four preferred embodiments is not simply a selection of size.

According to the memory device and the manufacturing method thereof disclosed in the above embodiments of the invention, the first lateral surface and the second lateral surface are formed in two stages, such that the protecting layer completely fills the space between the memory units along the shape of the insulating side-wall during the formation of the protecting layer, and no hole will be formed.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of memory device, comprising:
providing a substrate having a substrate surface;
forming at least two memory units separated via a space on the substrate;
forming an insulating layer covering the memory units and the substrate surface;
forming a mask layer only covering the bottom of the insulating layer on the insulating layer;
etching the part of the insulating layer partially covered by the mask layer;
removing the mask layer;
etching the part of the insulating layer where the mask layer is removed; and
forming a protecting layer on the memory units and in the space between the memory units.

2. The manufacturing method of memory device according to claim 1, wherein the insulating layer is composed of a silicon oxide/silicon nitride/silicon oxide stack structure.

3. The manufacturing method of memory device according to claim 1, wherein the insulating layer is composed of silcon oxide only.

4. The manufacturing method of memory device according to claim 1, wherein the insulating layer is composed of silcon nitride only.

5. The manufacturing method of memory device according to claim 1, wherein in the step of forming the insulating layer, the thickness of the insulating layer is smaller than a half of the width of the space.

6. The manufacturing method of memory device according to claim 1, wherein the mask layer is a photoresist layer.

7. The manufacturing method of memory device according to claim 1, wherein the mask layer is a bottom anti-reflective coating (BARC) layer.

8. The manufacturing method of memory device according to claim 1, wherein the mask layer is a combination of a photoresist layer and a bottom anti-reflective coating (BARC) layer.

9. The manufacturing method of memory device according to claim 1, wherein the mask layer is substantiality lower than a half height of the insulating layer.

10. The manufacturing method of memory device according to claim 1, wherein the step of forming the mask layer further comprises:
spin-coating the mask layer on the whole of the insulating layer; and
removing a part of the mask layer such that the mask layer only covers the bottom of the insulating layer.

11. The manufacturing method of memory device according to claim 1, wherein in the step of etching the part of the insulating layer partially covered by the mask layer, the mask layer is etchbacked such that the thickness of the mask layer is reduced.

12. The manufacturing method of memory device according to claim 1, wherein the step of etching the top of the insulating layer partially covered by the mask layer and the step of etching the top and the bottom of the insulating layer where the mask layer is removed are exercised in the same chamber.

13. The manufacturing method of memory device according to claim 1, wherein the step of etching the top of the insulating layer partially covered by the mask layer and the step of etching the top and the bottom of the insulating layer where the mask layer is removed are exercised in different chambers respectively.

14. A memory device, comprising:
a substrate having a substrate surface;
at least two memory units disposed on the substrate, wherein the memory units are separated via a space;
at least two insulating side-walls respectively enclose the lateral side of each memory unit, wherein each insulating side-wall comprises:
a first insulating portion having a first lateral surface;
a second insulating portion having a second lateral surface, wherein the first insulating portion is disposed on the second insulating portion; and
a protecting layer formed on the memory units and in the space between the memory units; wherein
the contained angle between the substrate surface and each first lateral surface is smaller than 75 degrees;
the contained angle between the substrate surface and each second lateral surface is smaller than 90 degrees.

15. The memory device according to claim 14, wherein the ratio of the height of each second insulating portion to the distance between the two second insulating portions is smaller than 0.6.

16. The memory device according to claim 14, wherein the ratio of the thickness of each second insulating portion to the distance between the two second insulating portions ranges 0.3˜0.65.

17. The memory device according to claim 14, wherein
the contained angle between the substrate surface and each first lateral surface is smaller than 70 degrees;
the contained angle between the substrate surface and each second lateral surface is smaller than 85 degrees;
the ratio of the height of each second insulating portion to the distance between the two second insulating portions is smaller than 0.6; and
the ratio of the thickness of each second insulating portion to the distance between the two second insulating portions ranges 0.5˜0.65.

18. The memory device according to claim 14, wherein
the contained angle between the substrate surface and each first lateral surface is smaller than 70 degrees;
the contained angle between the substrate surface and each second lateral surface ranges 85˜90 degrees;
the ratio of the height of each second insulating portion to the distance between the two second insulating portions is smaller than 0.2; and
the ratio of the thickness of each second insulating portion to the distance between the two second insulating portions ranges 0.3˜0.5.

19. The memory device according to claim 14, wherein
the contained angle between the substrate surface and each first lateral surface ranges 70˜75 degrees;
the contained angle between the substrate surface and each second lateral surface is smaller than 85 degrees;
the ratio of the height of each second insulating portion to the distance between the two second insulating portions is smaller than 0.4; and
the ratio of the thickness of each second insulating portion to the distance between the two second insulating portions ranges 0.3˜0.5.

20. The memory device according to claim 14, wherein
the contained angle between the substrate surface and each first lateral surface ranges 70˜75 degrees;
the contained angle between the substrate surface and each second lateral surface ranges 85˜90 degrees;
the ratio of the height of each second insulating portion to the distance between the two second insulating portions is smaller than 0.2; and
the ratio of the thickness of each second insulating portion to the distance between the two second insulating portions to ranges 0.4˜0.6.

21. The memory device according to claim 14, wherein each insulating side-wall is composed of silicon oxide and silicon nitride.

22. The memory device according to claim 14, wherein each insulating side-wall is composed of a silicon oxide/silicon nitride/silicon oxide stack structure.

23. The memory device according to claim 14, wherein each insulating side-wall is composed of silicon oxide only.

24. The memory device according to claim 14, wherein each insulating side-wall is composed of silicon nitride only.
